(19) United States
(12) Patent Application Publication
(10) Pub. No.: US 2005/0167734 A1
(43) Pub. Date: Aug. 4, 2005

(54) Flash memory devices using large electron affinity material for charge trapping

(75) Inventors: Min She, Boise, ID (US); Tsu-Jae King, Fremont, CA (US)

Correspondence Address: BEYER WEAVER & THOMAS LLP, P.O. BOX 70250, OAKLAND, CA, 94612-0250, US

(73) Assignee: THE REGENTS OF THE UNIVERSITY OF CALIFORNIA, Oakland, CA (US)

(21) Appl. No.: 10/993,602

(22) Filed: Nov. 19, 2004

Related U.S. Application Data
(60) Provisional application No. 60/537,928, filed on Jan. 20, 2004.

(51) Int. Cl. H01L 29/788

(52) U.S. Cl. 257/321

(57) ABSTRACT

Disclosed is a novel flash memory device using a high-permittivity dielectric such as HfO₂ or TiO₂ as a charge trapping layer. Numerical simulation shows that the novel trapping material will enhance the retention time/programming speed ratio by 5 orders of magnitude, compared to the conventional Si₃N₄ trapping layer. Capacitors with HfO₂ deposited by RTCVD as the charge trap/storage layer in SONOS-type flash memory devices were fabricated and characterized. Compared against devices with Si₃N₄ trapping layer, faster programming speed as well as good retention time is achieved with low programming voltage.

### CROSS REFERENCE TO RELATED APPLICATIONS

This application claims priority under 35 USC 120 from Provisional patent application Ser. No. 60/537,928, filed Jan. 20, 2004 which is incorporated herein by reference for all purposes.

### BACKGROUND OF THE INVENTION

This invention relates generally to semiconductor memory devices, and more particularly the invention relates to field effect transistors having a charge storage layer between a channel region and a control gate for programming the threshold voltage for current conduction in the channel.

Memory is a key component of any electronic system such as a personal computer, cellular phone, digital camera, network router, handheld personal digital assistant, etc. Demand for increased memory capacity and lower cost drives the miniaturization of semiconductor memory cells and also dictates low-power cell designs for use in future portable electronic systems.

There are mainly three kinds of semiconductor memory in the market: DRAM, SRAM and flash (non-volatile) memory. Although DRAM dominates the memory market, flash memory is rapidly gaining market share.

Dynamic-Random-Access Memory (DRAM) is the primary type of memory used in computers for core memory. A binary digit (“bit”) of information is stored in the form of electronic charge on a capacitor in each cell of a DRAM. It is difficult to scale down the DRAM cell size due to need for a sizable cell capacitance, however. The data retention capability of DRAM is limited by charge leakage through p-n junctions and sub-threshold conduction in transistors; therefore DRAM needs frequent refreshing with attendant power consumption.

In contrast with DRAM, flash memory does not require refreshing at all. Performance requirements for flash memory technology include: scalability, fast programming speed at low programming voltage, and 10-year retention time at 85° C. (for commercial electronic devices). A typical flash memory cell design consists of a single transistor with a double-poly-Si gate stack structure to achieve high density; see FIG. 1. Electrons are stored in the “floating gate” electrode that is electrically isolated from the transistor channel and control gate by dielectric insulating layers. The tunnel oxide layer between the channel and the floating gate must be thicker than 8 nm to guarantee 10 years retention time. This thickness makes the cell relatively slow to program, even if channel hot electron injection is used. Typical programming voltages required are 15˜18 V to achieve programming speed on the order of milliseconds (ms) by Fowler-Nordheim tunneling.

Recently, the SONOS (poly-Si-oxide-nitride-oxide-silicon) flash memory device, shown in FIG. 2, has attracted much attention due to its advantages over the traditional floating-gate flash memory device, which include a lower programming voltage and better scalability. Typically, a SONOS memory cell can be programmed with 10V gate bias, making SONOS memory suitable for embedded memory applications.

However, SONOS memory technology faces challenges for further improvement. For example, the tunnel oxide thickness cannot be reduced to below 25 Å (2.5 nm) to improve the programming speed, if 10 years retention time must be guaranteed. As shown in the energy-band diagrams of FIG. 2 and particularly in FIG. 3(b), there are two charge-loss mechanisms: (1) direct quantum-mechanical tunneling, with an associated tunnel barrier height φ₀+Et; and (2) thermally assisted de-trapping into the nitride conduction band and subsequent quantum-mechanical tunneling through the tunnel oxide, with associated tunnel barrier height φ₀. A high conduction-band offset φ₀ between the trapping layer and the tunnel oxide is essential for achieving long retention time. The offset φ₀ for a nitride-trapping layer is only 1.03 eV. Programming speed is also limited due to the fact that electrons must tunnel through a significant portion of the nitride before becoming trapped (modified FN tunneling as shown in FIG. 3(a), especially at low programming voltages.

### SUMMARY OF THE INVENTION

In accordance with the invention, a gate-stack structure is provided for a flash memory device which includes a tunnel dielectric layer on a surface of a semiconductor body over a channel region of the device. An electron-trapping dielectric layer having a permittivity higher than the permittivity of silicon nitride (Si₃N₄) overlies the tunnel dielectric layer and has electron trapping sites (“traps”) therein. As used herein “high permittivity” means high when compared to the permittivity of Si₃N₄.

A control dielectric overlies the high permittivity dielectric layer, and a control gate is on the control dielectric layer and overlying the high permittivity dielectric layer and channel region.

In preferred embodiments, the electron trapping dielectric layer comprises TiO₂, HfO₂, or other high-permittivity dielectric material.

The invention and other objects and features thereof will be more readily apparent from the following detailed description and appended claims when taken with the drawings.

### BRIEF DESCRIPTION OF THE DRAWINGS

FIG. 1 is a section view of a typical floating-gate double-poly-Si flash memory device.

FIG. 2 is a section view of SONOS memory device structure.

FIGS. 3a and 3b are electron energy-band diagrams illustrating that during programming, electrons tunnel through a portion of the nitride-trapping layer and that a large barrier height φ₀ will block electron leakage effectively and improve retention time.

FIG. 4 illustrates simulated programming characteristics for a SONOS-type memory device with either HfO₂ or Si₃N₄ as the charge-trapping layer material.

FIG. 5 illustrates simulated retention characteristics vs. trap energy level, for a SONOS-type memory device either HfO₂ or Si₃N₄ as the charge-trapping layer material.

FIG. 6 illustrates measured programming characteristics for SONOS-type memory devices with different charge trapping layer materials.

FIG. 7 illustrates charge retention characteristics for SONOS-type memory devices with different charge trapping layer materials.

FIG. 8 illustrates charge retention characteristics for SONOS-type memory devices with different charge trapping layer materials, programmed to the same flatband voltage V_{FB}.

FIG. 9 illustrates V_{FB} shift vs. gate programming voltage, for different programming pulse times, for SONOS-type memory devices with either HfO₂ or Si₃N₄ as the charge-trapping layer material.

FIGS. 10a-10c illustrate electron energy-band diagrams for flash memory devices with either poly-Si (floating gate) or TiO₂ (trapping layer) for charge storage, and a section view of a poly-Si floating-gate device having a defect chain in the tunnel oxide by which the stored charge leaks away, respectively.

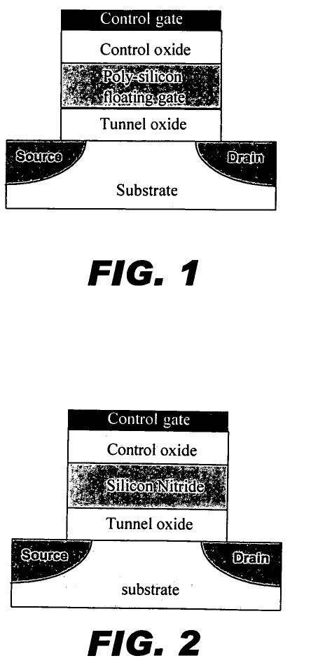

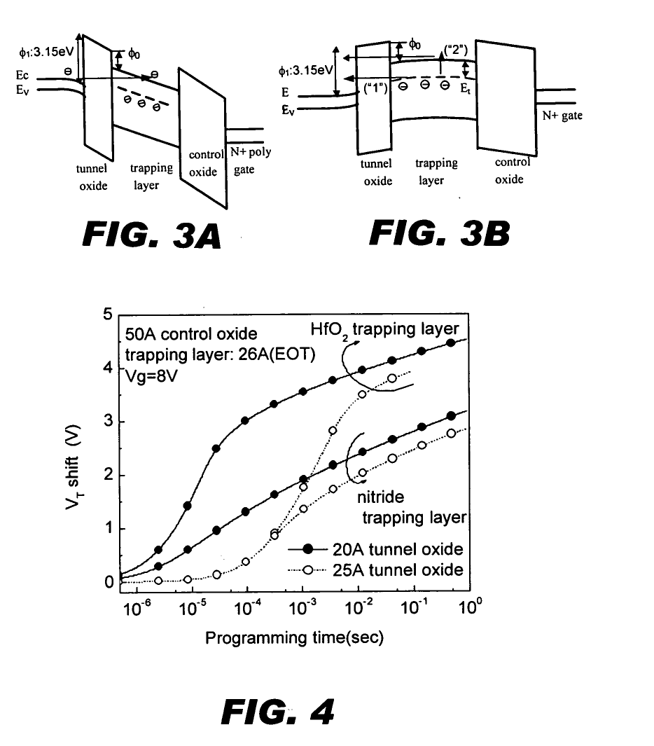

### DETAILED DESCRIPTION OF ILLUSTRATED EMBODIMENTS

In order to improve the programming speed and/or lower the programming voltage of a SONOS-type memory device, it is desirable to use an electron-trapping material with a lower conduction band edge (higher electron affinity) to achieve a larger offset φ₀, as well as to provide for programming by direct tunneling at low voltages. In accordance with the invention, a high-permittivity (“high-k”) dielectric material such as HfO₂ or ZrO₂ replace silicon nitride as the electron trapping material. Such materials have a lower conduction band edge than does silicon nitride. A comparison of dielectric material properties is given in Table 3. If HfO₂ were to be used as the trapping layer, φ₀ would be 1.65 eV, which is much better than the 1.03 eV barrier associated with a nitride-trapping layer. Thus, it is advantageous to use a high-k material as the trapping layer in a SONOS-type memory device, provided that it contains a sufficient density of deep trap states. In principle, the trap density and trap energy level in a high-k trapping layer can be tuned by adjusting the deposition process parameters.

TABLE 3
Trapping material properties

Material

| | Si₃N₄ | HfO₂ | ZrO₂ | TiO₂ |
|---|---|---|---|---|
| Conduction | 2.12 | 1.5 | 1.5 | ˜0 |
| band height | | | | |
| (eV)* | | | | |
| φ₀ (eV) | 1.03 | 1.65 | 1.65 | 3.15 |
| K | 7.5 | 24 | 24 | ˜60 |
| Eₜ(eV) | 0.8˜1.0[8] | 0.9 | 1.0[7] | |
| | | [this work] | | |

*Relative to the silicon conduction band.

Device Modeling—During programming, the total charge injected into the trapping layer is

$${Q}_{t} = {\int }_{0}^{{t}_{w}} J ( t ) ⅆ t \qquad ( 1 )$$

where J(t) is the density of current injected from the channel inversion-layer into the conduction band of the trapping layer. The resultant threshold voltage (V_{T}) shift can be calculated in the same way as described in [8]. FIG. 4 shows the simulated programming characteristics. For 20 Å tunnel oxide thickness, a HfO₂ trapping layer can provide 3 orders of magnitude faster programming speed, to achieve 2.5V V_{T} shift.

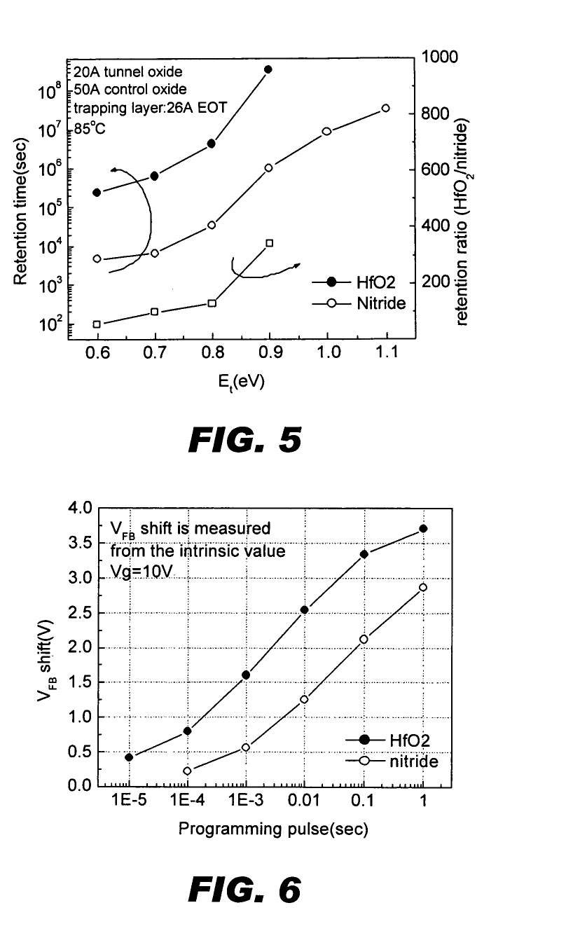

During retention, the electron leakage rate can be modeled as:
dQₜ/dt=−(e_{dt}+eₜₕ)Qₜ (2)
Where e_{hd} and eₜₕ are the direct tunneling leakage rate and thermal de-trapping leakage rate, respectively. The simulated retention characteristics are shown in FIG. 5. The HfO₂ trapping layer provides at least 2 orders of better retention than a nitride trapping layer, for a wide range of trap energy levels.

Device Fabrication and Characterization: N+ poly-Si gated capacitors with tunnel-oxide/trapping-layer/control-oxide dielectric stacks were fabricated on n-type Si substrates. Devices with HfO₂ or Si₃N₄ as the trapping layer are designated “device H” or “device N”, respectively. Both types of devices have the same areal gate capacitance. Details of the gate stack fabrication process are given in Table 4. HfO₂ was deposited in a RTCVD system at 500° C. with Hf-Butoxide precursor. The devices were UV-erased before measurement. The measured intrinsic flat-band voltage (V_{FB}) for “device H” was 0.3V, whereas that for “device N” was −0.41V. Since the theoretical V_{FB} value is −0.21V, the HfO₂ and Si₃N₄ trapping layers contain negative and positive fixed charge Q_{f}, respectively.

TABLE 4
Gate-stack fabrication process details.

| | |
|---|---|
| Tunnel oxide: | 2 nm, grown at 800° C. in N₂-diluted O₂ ambient |
| Trapping layer: | 4.5 nm SiN by LPCVD at 750° C. with DCS:NH₃ = 1:1 |
| | (“device N”) |
| | 14.0 nm HfO₂ by RTCVD at 500° C. (“device H”) |
| Control oxide: | 7.5 nm HTO SiO₂ by LPCVD at 800° C. |
| Annealing: | 30 min. 900° C. in N₂ ambient. |

Note:
In both devices, a thin layer of 2 nm nitride was deposited at 680° C. with
DCS:NH₃ = 1:3 before trapping layer formation to prevent interfacial layer growth during the high temperature anneal.

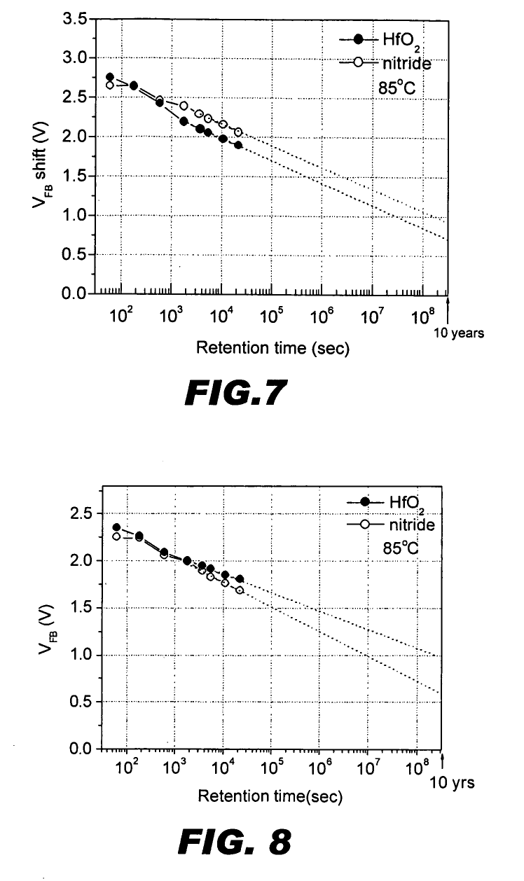

Programming characteristics for both devices are shown in FIG. 6. The HfO₂ trapping layer offers more than 40× faster programming speed, for a 2.5V V_{FB} shift. Without the negative fixed charge, “device H” would program even more quickly. This is because the negative fixed charge reduces the electric field, from 7.9 MV/cm to 7.4 MV/cm at the beginning of the programming pulse, and from 6.0 MV/cm to 5.5 MV/cm at the end of the programming pulse. FIG. 7 shows data retention characteristics at 85° C. “Device H” can retain >0.5V VFB shift after 10 years. “Device N” shows slightly better (˜6×) retention. This may be due to the presence of fixed negative charge in the HfO₂ layer, which increases the electric field across the tunnel oxide in retention mode, resulting in a higher rate of charge loss. If both devices are programmed to the same V_{FB} so that the electric field during retention is the same, then “device H” retains charge better than “device N”, as shown in FIG. 8.

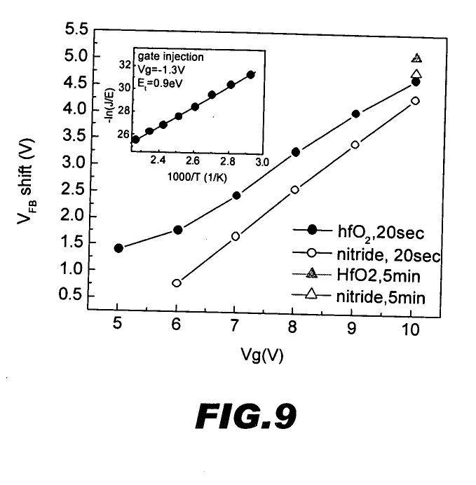

If the figure of merit is defined as the ratio of programming speed to retention time, “device H” exhibits ˜7× better performance even with significant negative fixed charge. FIG. 9 compares the V_{FB} shifts as a function of programming voltage. The real trap density is estimated to be 1×10¹³/cm² in each device. The trap energy level in HfO₂ is estimated to be 0.9 eV from Frenkel-Poole current measurements under gate injection. It should be noted that the HfO₂ deposition process was not optimized in this work. By reducing the negative fixed charge in the HfO₂ material, even better performance characteristics should be attainable.

As noted above, there are mainly two types of flash memories: the floating gate flash memory and the SONOS-type flash memory. The advantage of using low barrier material such as HfO₂ and TiO₂ to replace conventional silicon nitride trapping layer in the SONOS-type flash memory has been demonstrated in our work. Further, these new materials can make the floating gate flash memory more scalable. TiO₂ as the trapping-layer dielectric material is discussed below.

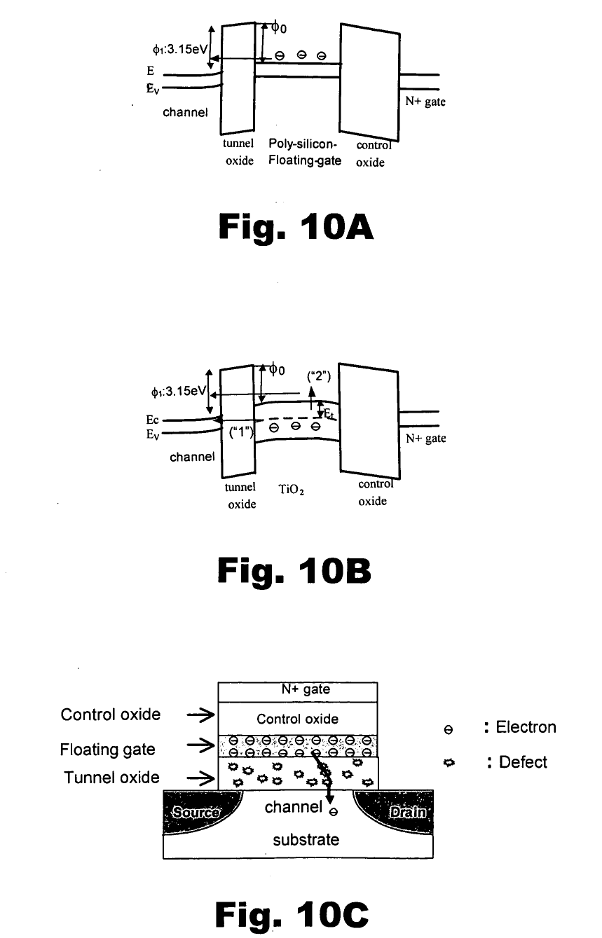

The conduction band edge of TiO₂ relative to the silicon conduction band edge is nearly 0 eV; that is, TiO₂ has a conduction-band-edge energy level comparable to that of a poly-Si floating gate electrode. The energy-band diagrams during retention are compared in FIGS. 10(a) and 10(b) and a section view of the floating-gate flash memory device structure is shown in FIG. 10(c). There are two disadvantages of the floating-gate flash memory device design: 1) Electrons are stored in the conduction band of the floating gate material, and it is very easy for them to leak back to the channel conduction band, as shown in FIG. 10(a). 2) The floating gate material is an electrically conductive material, so the electrons can move freely through it; thus, if there is a defect chain inside the tunnel oxide, as shown in FIG. 10c, all of the electrons in the floating gate can leak back to the channel or source/drain regions through the defect chain one-by-one. This is why very thick tunnel oxide (>8 nm) is needed to guarantee 10 years retention time in a floating-gate flash memory device.

The above disadvantages can be eliminated by using TiO₂ as the electron-storage material rather than poly-Si. Electrons are stored in trap states within the TiO₂ layer as shown in FIG. 10(b). The trap energy level (˜0.9 eV below the conduction band edge) is assumed to be as the same as that for HfO₂. Firstly, electron leakage back to the channel through the tunnel oxide—path (1)—is negligible since electrons can only tunnel back to energy states located within the band gap of the silicon substrate, where the density of empty states is very small. If electrons leak away via path (2) to the Si conduction band, they need to first be thermally de-trapped into the TiO₂ conduction band, with a de-trapping probability of 2.2 E-13 at 85° C. This low de-trapping probability makes the leakage current through path (2) much smaller than that in the floating gate memory device. Secondly, TiO₂ is an insulating material, so electrons cannot move freely within it. Even if there exists a defect chain in the tunnel oxide as shown in FIG. 10(c), only the electrons trapped directly above the defect chain will be affected. The electrons trapped elsewhere within the TiO₂ will not be able to move to the location where the defect chain is, and hence they will not leak back to the channel one-by-one.

Although HfO₂ and TiO₂ electron-trapping materials are described above, other trapping materials can be used in the flash memory device. A good electron-trapping material should possess the following material properties. First, it should be an electrical insulator or semi-insulator so that electrons cannot move freely within it. Second, it should contain deep-energy-level traps of sufficient areal density. Third, the conduction-band-edge energy should be low relative to that of the semiconductor channel, to favor both carrier injection into the trapping layer and long retention time. Fourth, the energy band gap of the trapping material should not be too small. A small band gap will limit the depth of the trap energy level. If the band gap is too small, valence-band electrons in the trapping layer may be thermally injected into the conduction band and then leak back to the channel.

Herein has been described a novel flash memory device using a large electron affinity dielectric material such as HfO₂ and TiO₂ for charge trapping. Experimental results have confirmed that a HfO₂-trap based memory device has much better performance than a conventional silicon-nitride (Si₃N₄) based flash memory device. Theoretical considerations show that a TiO₂ based memory device can achieve much longer retention time than a conventional floating-gate flash memory device while maintaining comparable programming speed. New trapping materials can be used in flash memory devices to enhance performance.

While the invention has been described with reference to specific embodiments, the description is illustrative of the invention and is not to be construed as limiting the invention. Various modifications and applications may occur to those skilled in the art without departing from the true scope and spirit of the invention as defined by the appended claims.

1. A flash memory device comprising:
a) a semiconductor body including in one surface source and drain regions separated by a channel region,
b) an electron tunnel dielectric layer on the surface of the semiconductor body over the channel region,
c) a high permittivity dielectric layer on the tunnel dielectric layer, the high permittivity dielectric layer having electron traps therein,
d) a control dielectric layer on the high permittivity dielectric layer, and
e) a control gate layer on the control dielectric layer.

2. The flash memory device as defined by claim 1 wherein the high permittivity dielectric layer comprises HfO2.

3. The flash memory device as defined by claim 2 wherein the electron tunnel dielectric layer comprises SiO2.

4. The flash memory device as defined by claim 3 wherein the control dielectric comprises SiO2.

5. The flash memory device as defined by claim 4 wherein the control gate layer comprises polycrystalline silicon.

6. The flash memory device as defined by claim 1 wherein the high permittivity dielectric layer comprises TiO2.

7. The flash memory device as defined by claim 6 wherein the electron tunnel dielectric layer comprises SiO2.

8. The flash memory device as defined by claim 7 wherein the control dielectric comprises SiO2.

9. The flash memory device as defined by claim 8 wherein the control gate layer comprises polycrystalline silicon.

10. In a transistor for use in flash memory, a gate structure for the transistor comprising:
a) an electron tunnel dielectric layer on the surface of a semiconductor body over a channel region of the transistor,
b) a high permittivity dielectric layer on the tunnel dielectric layer, the high permittivity dielectric layer having electron traps therein,
c) a control dielectric layer on the high permittivity dielectric layer, and
d) a control gate layer on the control dielectric layer.

11. The gate structure as defined by claim 10 wherein b) is selected from the group consisting of TiO2 and HfO2.

12. A transistor including a channel region, a control gate for controlling current conduction in the channel region, and a charge-trapping layer between the channel region and the control gate, electron charge in the charge-trapping layer establishing a threshold control-gate voltage level for channel current conduction, the charge-trapping layer comprising a high-permittivity dielectric material.

13. The transistor as defined by claim 12 and including a source region at one end of the channel region and a drain region at an opposing end of the channel region.

14. The transistor as defined by claim 13 and further including a dielectric layer between the charge-trapping layer and the channel region.

15. The transistor as defined by claim 14 wherein the dielectric layer comprises an electron tunnel dielectric layer.

16. The transistor as defined by claim 15 and further including a control dielectric between the control electrode and the charge-trapping layer.

17. The transistor as defined by claim 14 and further including a control dielectric between the control electrode and the charge-trapping layer.

18. In a transistor having a source region and a drain region separated by a channel region, a gate structure for controlling conduction of the channel region comprising:
a) a high permittivity dielectric layer overlying and spaced from the channel region and having charge traps therein, and
b) a control gate layer overlying and spaced from the high permittivity dielectric layer for receiving a signal for controlling conduction in the channel, whereby charge trapped in the high permittivity dielectric layer affects the control-gate threshold voltage for current conduction in the channel region.

19. The gate structure as defined by claim 18 and including a dielectric layer between the high permittivity dielectric layer and the channel region.

20. The gate structure as defined by claim 19 wherein the dielectric layer comprises an electron tunnel dielectric layer.

21. The gate structure as defined by claim 20 further including a control dielectric between the control electrode and the high permittivity dielectric layer.

22. The gate structure as defined by claim 21 wherein the high permittivity dielectric layer comprises a multi-layered charge-trapping layer.

23. The gate structure as defined by claim 18 wherein the high permittivity dielectric layer comprises a multi-layered charge-trapping layer.
